(19) United States
(12) Patent Application Publication
(10) Pub. No.: US 2016/0133559 A1
(43) Pub. Date: May 12, 2016

(54) SEMICONDUCTOR STRUCTURE AND MANUFACTURING METHOD THEREOF

(71) Applicant: UNITED MICROELECTRONICS CORP., Hsin-Chu City (TW)

(72) Inventors: Jui-Fa Lu, Tainan City (TW); Chin-Chun Huang, Tai-Chung City (TW); Chun-Nien Chen, Tainan City (TW)

(21) Appl. No.: 14/537,913

(22) Filed: Nov. 11, 2014

(51) Int. Cl. H01L 23/528; H01L 29/423; H01L 21/768; H01L 21/22; H01L 49/02; H01L 27/06

(52) U.S. Cl. CPC H01L 23/528; H01L 28/10; H01L 28/60; H01L 27/0629; H01L 27/0617; H01L 21/768; H01L 21/22; H01L 29/42372

(57) ABSTRACT

A semiconductor structure includes a substrate comprising a plurality of layers formed thereon, at least a first device formed in one of the layers formed thereon, a drawn region enclosing the first device, and a plurality of dummy structures in another layer. The dummy structures are formed in a first region correspondingly outside of the drawing region and in a second region correspondingly inside of the drawing region.

### BACKGROUND OF THE INVENTION

1. Field of the Invention

The invention relates to a semiconductor structure and manufacturing method thereof, and more particularly, to a semiconductor structure with dummy structures and manufacturing method thereof.

2. Description of the Prior Art

In modern ultrafine semiconductor devices, there are formed huge number of devices on a substrate as a result of increased integration density, and because of this, there are formed extremely complex interconnection structures in many layers in order to construct electrical connections.

Furthermore, in the semiconductor integrated circuit (hereinafter abbreviated as IC), it is practiced to secure planar surface for the interlayer insulation films by forming, in each of the interlayer insulation films, dummy structures in correspondence to the regions where the interconnection structures or the devices are sparsely distributed.

However, there may some regions that the dummy structures are avoided. For example, in analog and mixed signal ICs that reply on high quality passive devices such as capacitors and inductors, dummy block regions correspondingly enclosing those passive devices are often drawn in many layers because the dummy structures, which often include conductive material, may detrimentally affect circuit performance. That is, the dummy block region is often drawn to enclose some devices not only in the layer where such devices are formed, but also in the layers under and above the layer where such devices are formed.

Though the dummy block regions are desirably required to some devices, it is found that other devices or interconnections in the dummy block region of other layers are adversely impacted in the fabricating process because the dummy structures are not provided. Therefore a semiconductor structure with the dummy structures and manufacturing method thereof is still in need.

### SUMMARY OF THE INVENTION

According to the claimed invention, a semiconductor structure is provided. The semiconductor structure includes a substrate including a plurality of layers formed thereon, at least a first device formed in one of the layers, a drawn region enclosing the device, and a plurality of dummy structures formed in another layer. The dummy structures are formed in a first region correspondingly outside of the drawing region and in a second region correspondingly inside of the drawing region.

According to the claimed invention, a method for manufacturing a semiconductor structure is provided. According to the method for manufacturing the semiconductor structure, a substrate including a plurality of layers formed thereon is provided. Next, at least a dummy block region in one of the layers is recognized. The dummy block region includes at least a device formed therein. After recognizing the dummy block region, a plurality of dummy structures are inserted in a first region outside of the dummy block region and in a second region inside of the dummy block region in the layer.

According to the claimed invention, another method for manufacturing a semiconductor structure is provided. According to the method for manufacturing the semiconductor structure, a substrate including a plurality of layers formed thereon is provided. Next, at least a device formed in a drawn region neighboring on a dummy-empty region in one of the layers is recognized. After recognizing the device, a plurality of dummy structures are inserted in a first region outside of the drawing region.

According to the semiconductor device and manufacturing method thereof, a dummy block region or a device neighboring on a dummy-empty region is recognized and thus the dummy structures are inserted into the dummy block region and the dummy-empty region. The inserted dummy structures are able to maintain uniform pattern density, and therefore those devices in the dummy block region or neighboring on the dummy-empty region are protected.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a method for manufacturing a semiconductor structure provided by a first preferred embodiment of the present invention.

FIGS. 2-4 are schematic drawings illustrating the method for manufacturing the semiconductor structure provided by the first preferred embodiment, wherein

FIG. 3 is an enlarged view of a portion of FIG. 2 and in a step subsequent to FIG. 2, and

FIG. 4 is a cross-sectional view taken along a Line A-A′ of FIG. 3.

FIG. 5 is a flow chart of a method for manufacturing a semiconductor structure provided by a second preferred embodiment of the present invention.

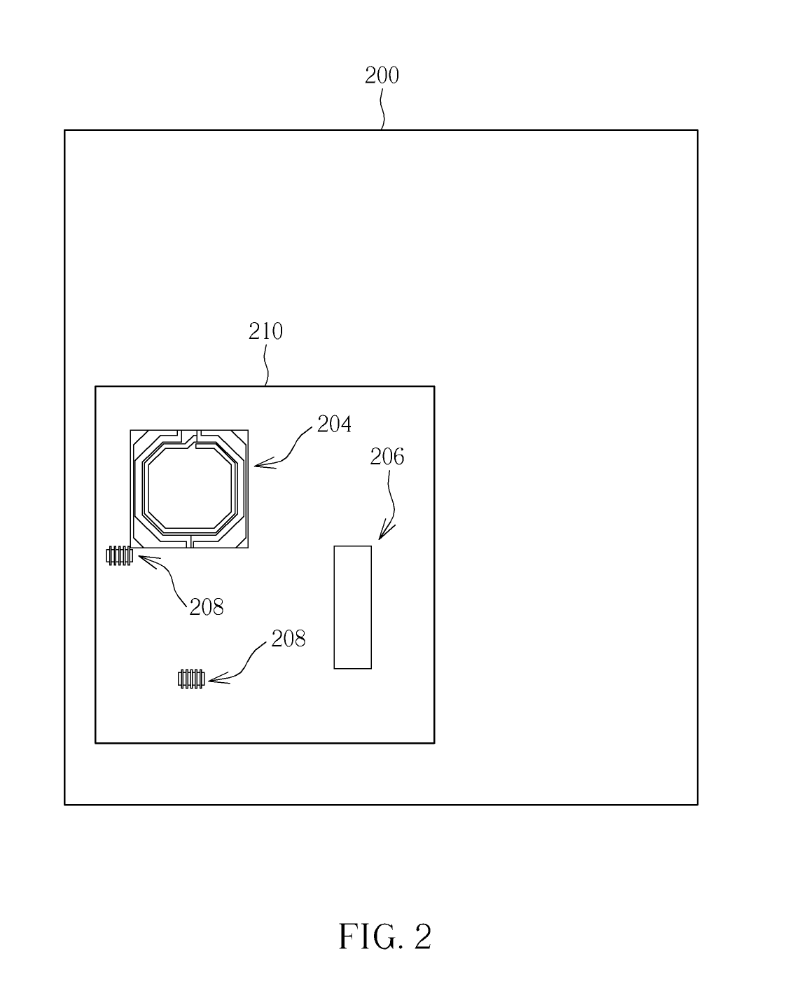

FIGS. 2 and 6-7 are schematic drawings illustrating the method for manufacturing the semiconductor structure provided by the second preferred embodiment, wherein

FIG. 6 is a is an enlarged view of a portion of FIG. 2, and

FIG. 7 is an enlarged view of a portion of FIG. 6 and in a step subsequent to FIG. 6.

FIG. 8 is a flow chart of a method for manufacturing a semiconductor structure provided by a third preferred embodiment of the present invention.

FIGS. 2, 6 and 9-10 are schematic drawings illustrating the method for manufacturing the semiconductor structure provided by the third preferred embodiment, wherein

FIG. 6 is a is an enlarged view of a portion of FIG. 2, and

FIG. 9 is an enlarged view of a portion of FIG. 6 and in a step subsequent to FIG. 6, and

FIG. 10 is a cross-sectional view taken a Line B-B′ of FIG.

9.

### DETAILED DESCRIPTION

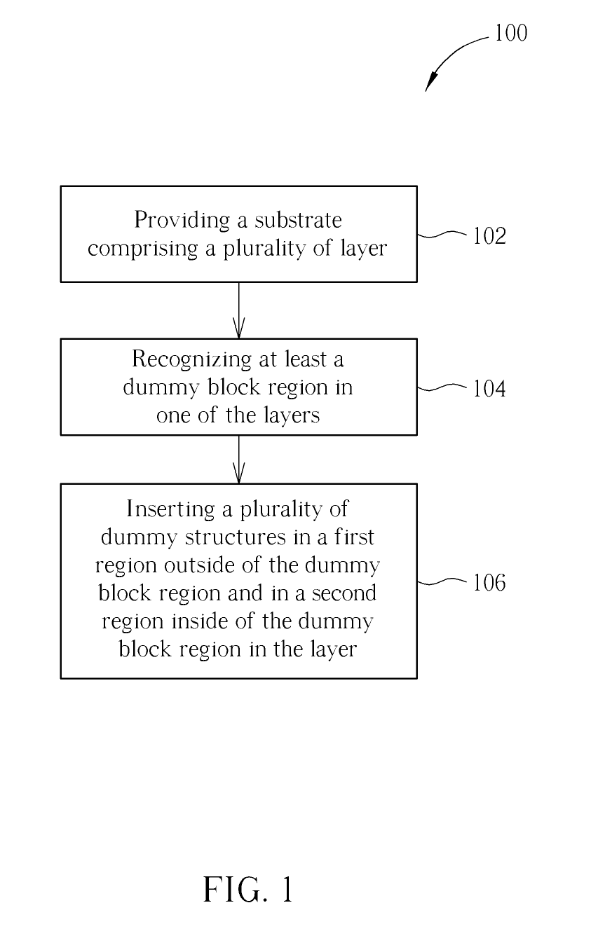

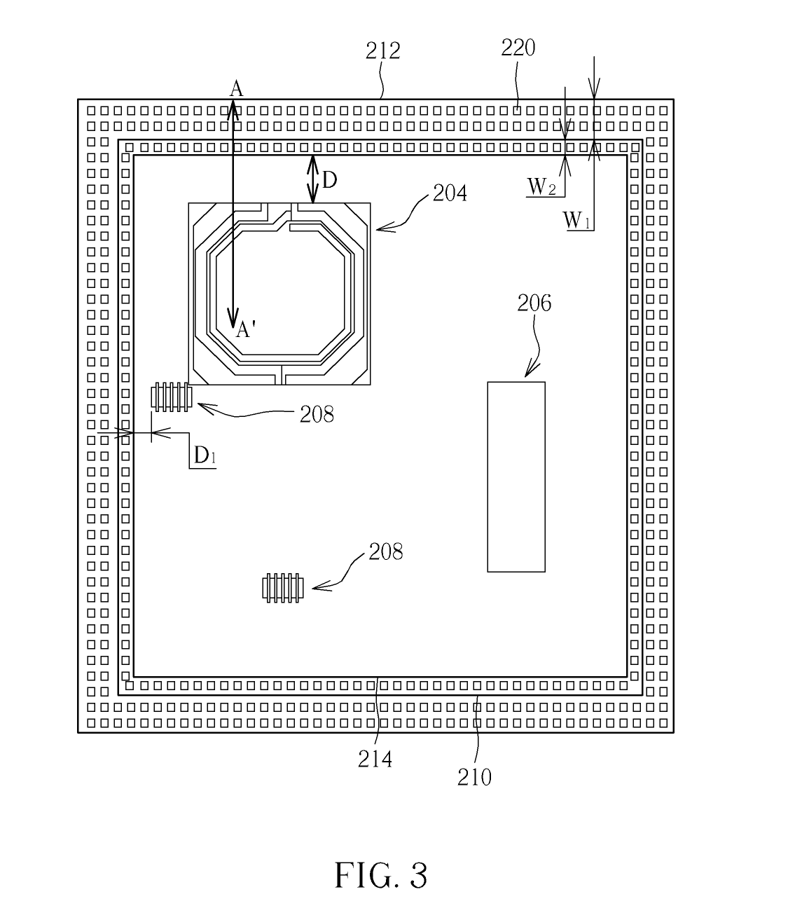

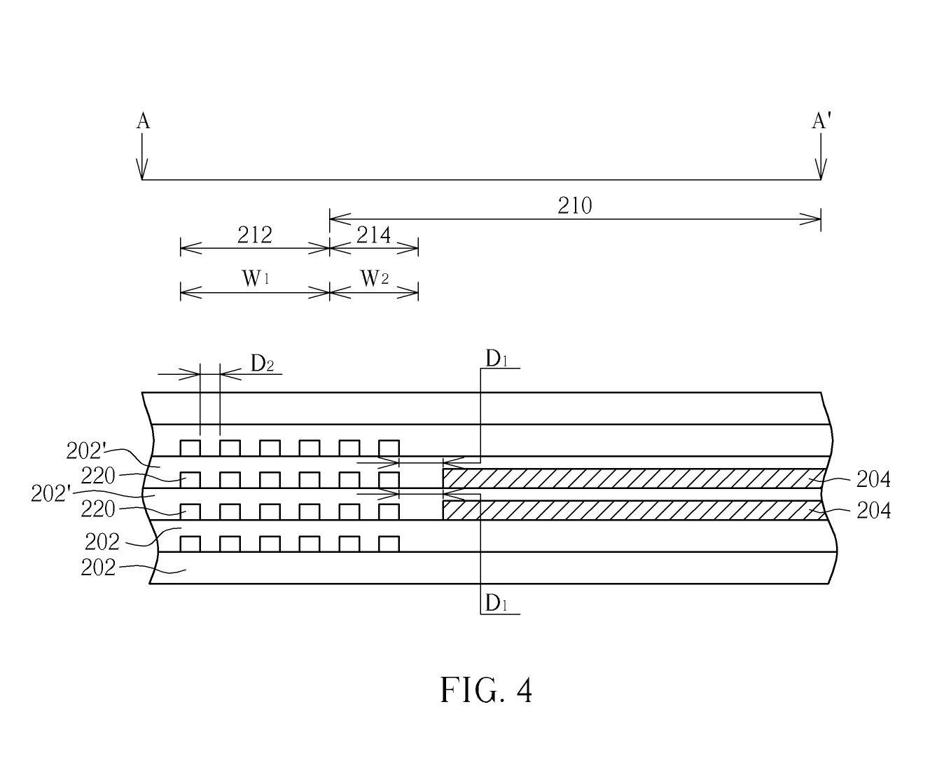

Please refer to FIGS. 1-4, FIG. 1 is a flow chart of a method for manufacturing a semiconductor structure provided by a first preferred embodiment of the present invention, FIGS. 2-3 are schematic drawings illustrating the method for manufacturing the semiconductor structure provided by the first preferred embodiment, and FIG. 4 is a cross-sectional view taken along a Line A-A′ of FIG. 3. As shown in FIG. 1, a method 100 for manufacturing a semiconductor structure is provided by the present invention, and the method 100 for manufacturing the semiconductor structure includes:

STEP 102: Providing a substrate comprising a plurality of layers

Please refer to FIG. 2 together with FIG. 1. As shown in FIG. 2, a substrate 200 including a plurality of layers 202 and 202′ (shown in FIG. 4) formed thereon is provided. Please note that the layers 202′ including devices formed therein are designated by 202′. The substrate 200 can be any wafer or chip in the-state-of-art. It is well-known to those skilled in the art that there are formed huge number of devices on the substrate 200 as a result of increased integration density. For example, devices such as at least an inductor 204, at least a metal-oxide-metal (hereinafter abbreviated as MOM) capacitor 206, and at least a device 208 are formed in the substrate 200. Additionally, the device 208 is referred to any active device required in ICs. In the preferred embodiment, the device 208 can be a metal-oxide-semiconductor (hereinafter abbreviated as MOS) transistor, but not limited to this. Furthermore, the device 208 can be a small device, and the “small device” is referred to a device having a gate layer of which a width W_{G} is smaller than 100 nm, preferably 40 nm-70 nm. It is noteworthy that since there are plural layers 202 and 202′ formed on the substrate 200, those above mentioned devices 204/206/208 can be formed on different layers 202′, but not limited to this.

The method 100 for manufacturing the semiconductor structure provided by the preferred embodiment further includes:

STEP 104: Recognizing at least a dummy block region in one of the layers

Please refer to FIG. 2 together with FIG. 1. Next, at least a dummy block region 210 in one of the layers 202 is recognized. It is noteworthy that area near the inductor 204 and/or the capacitor 206 is often defined to be the dummy block region 210, that is void of conductive material, by the customer or the manufacturer. And therefore, those devices such as the inductor 204 and the capacitor 206 will not be impacted by the dummy structures. More important, the dummy block region 210 is usually drawn to enclose not only the inductor 204 and/or the capacitor 206, but also the small device 208 neighboring on the inductor 204 and/or the capacitor 206, as shown in FIG. 2. In other words, the devices 204, 206, 208 formed in the dummy block region are neighboring on a dummy-empty region. The dummy-empty region is referred to a region that no dummy structure is formed in a 100 μm*100 μm area. It is noteworthy that the dummy block region 210 defined in not only the layer where the inductor 204 and/or the capacitor 206 is are located, but also in the layers under and above the layer where the inductor 204 and/or the capacitor 206 are formed.

The method 100 for manufacturing the semiconductor structure provided by the preferred embodiment further includes:

STEP 106: Inserting a plurality of dummy structures in a first region outside of the dummy block region and in a second region inside of the dummy block region in the layer.

Please refer to FIGS. 1 and 3-4 together. It should be noted that FIG. 3 is an enlarged view of the dummy block region 210 shown in FIG. 2 and in a step subsequent to FIG. 2. After recognizing the dummy block region 210, a plurality of dummy structures 220 are inserted and formed in a first region 212 outside of the dummy block region 210 and in a second region 214 inside of the dummy block region 210 in the layers 202. According to the preferred embodiment, the first region 212 includes a first width W₁, and the first width W₁ is between 15 μm and 30 μm. And the second region 214 comprises a second width W₂, and the second width W₂ is between 5 μm and 15 μm. Therefore, the dummy structures 220 (formed in the first region 212 and the second region 214) are formed in a ring shape around the dummy block region 210 as shown in FIG. 3.

Please refer to FIG. 4. It noteworthy that dummy structures 220 can be formed in the layer 202′ the same with the inductor 204, the capacitor 206, and/or the small device 208. When the dummy structures 220 are formed in the layer 202′ the same with the inductor 204, the capacitor 206, and/or the small device 208, a distance D₁ between the dummy structures 220 and any of the aforementioned device is larger than 0.6 μm, preferably larger than 1 μm. However, the dummy structures 220 can also be formed in the layer 202 under or above the layer 202′ where the inductor 204, the capacitor 206, and/or the small device 208 are formed. Furthermore, the dummy structures 220 include doped regions, polysilicon structures, or metal structures. And a distance D₂ between each dummy structure 220 is equal to or larger than 0.25 μm. It should be easily realized by those skilled in the art that though the size and density of the dummy structures 220 in the first region 212 and the second region 214 are the same, the size and the density of the dummy structures 220 in the first region 212 can be different from that of the dummy structures 220 in the second region 214 if required.

According to the method for manufacturing the semiconductor structure 100 provided by the first preferred embodiment, the dummy block region 210 previously defined by the customer or the manufacturer is recognized and followed by inserting/placing the dummy structures 220 in the first region 212 outside of the dummy block region 210 and in the second region 214 inside of the dummy block region 210. Accordingly, the dummy structures 220 form a dummy ring as shown in FIG. 3. The dummy structures 220 can be formed in the layer 202′ the same with the layer 202′ where the inductor 204, the capacitor 206, and/or the small device 208 are formed. Furthermore, the dummy structures 220 can be formed, correspondingly to the dummy block region 210, in the layer(s) 202 under and/or above the layer 202′ where the inductor 204, the capacitor 206, and/or the small device 208 are formed. Consequently, uniformity around the dummy block region 210 is improved.

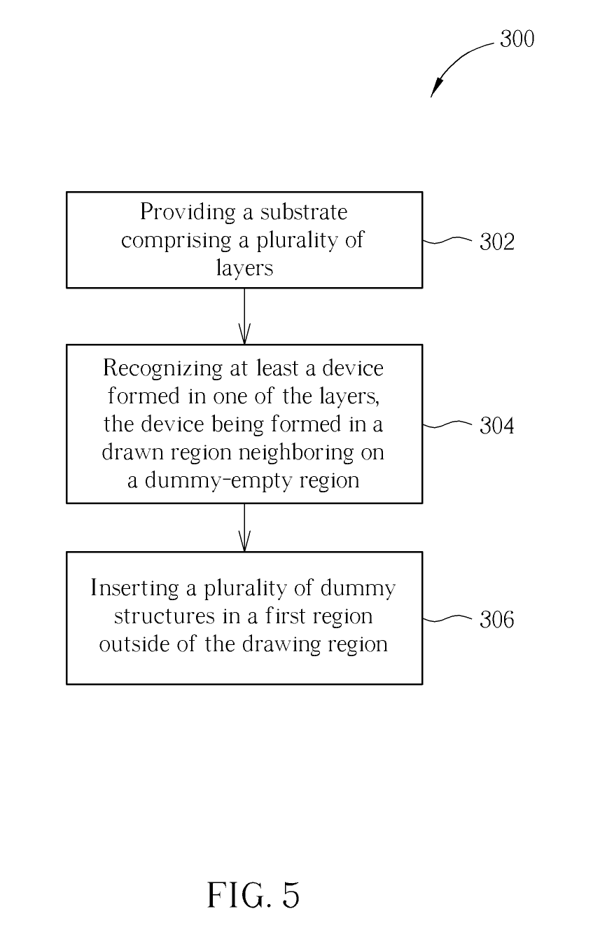

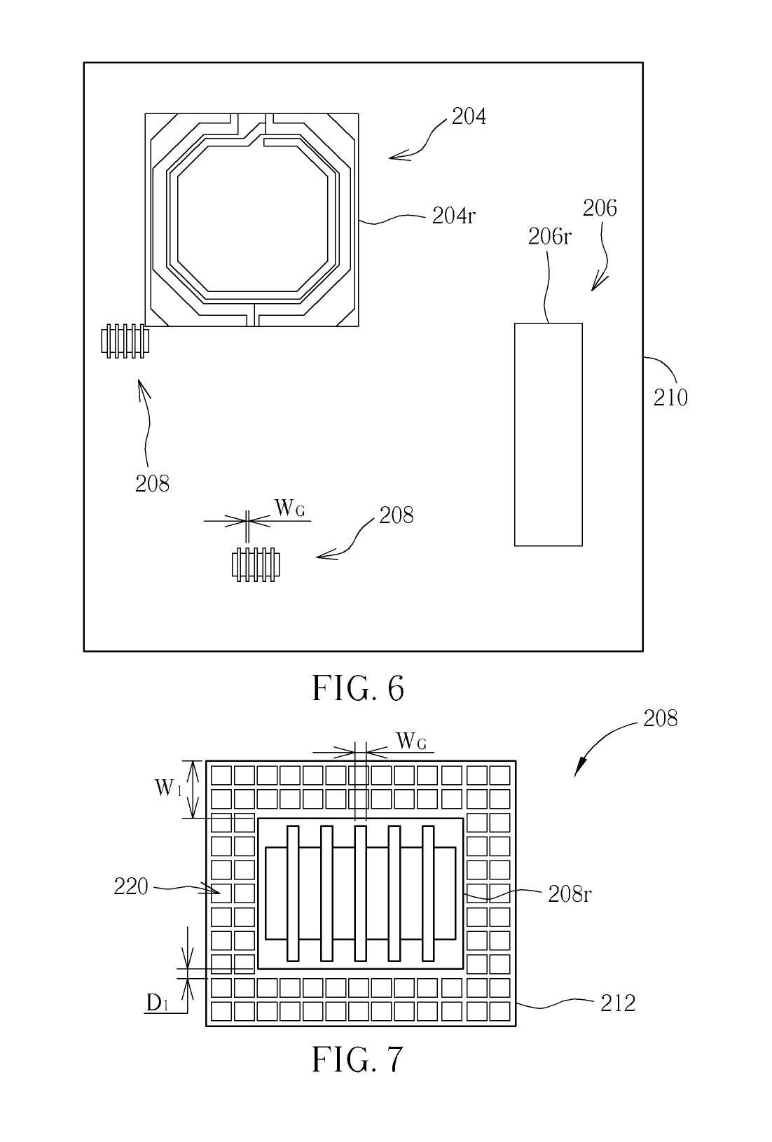

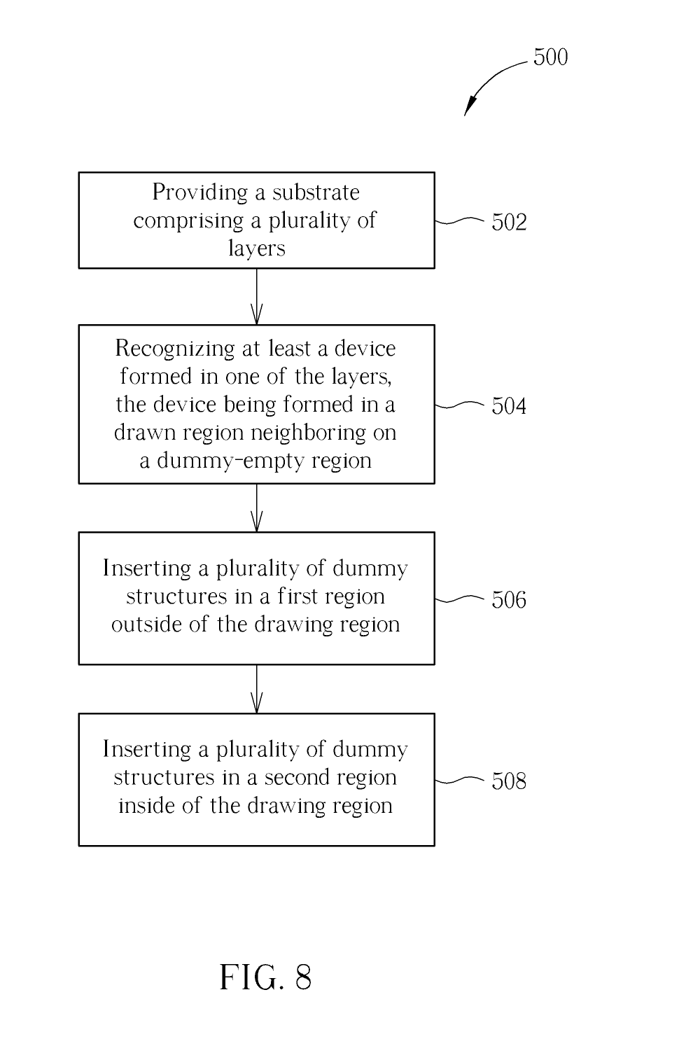

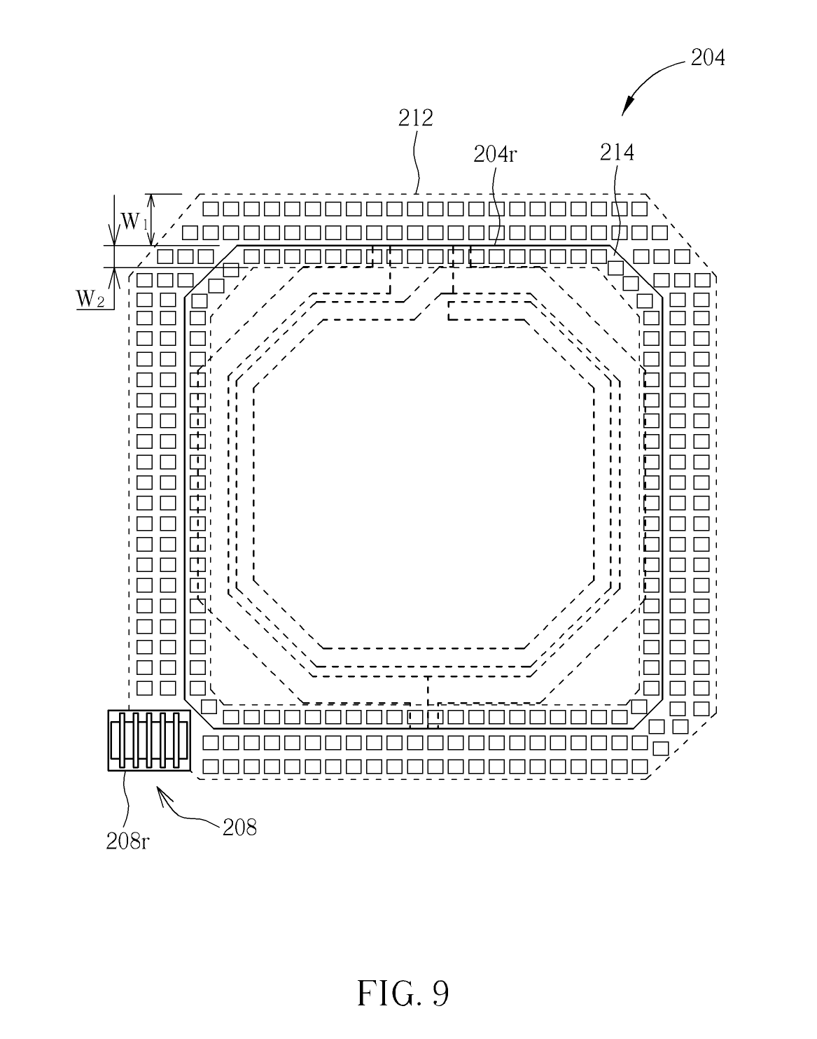

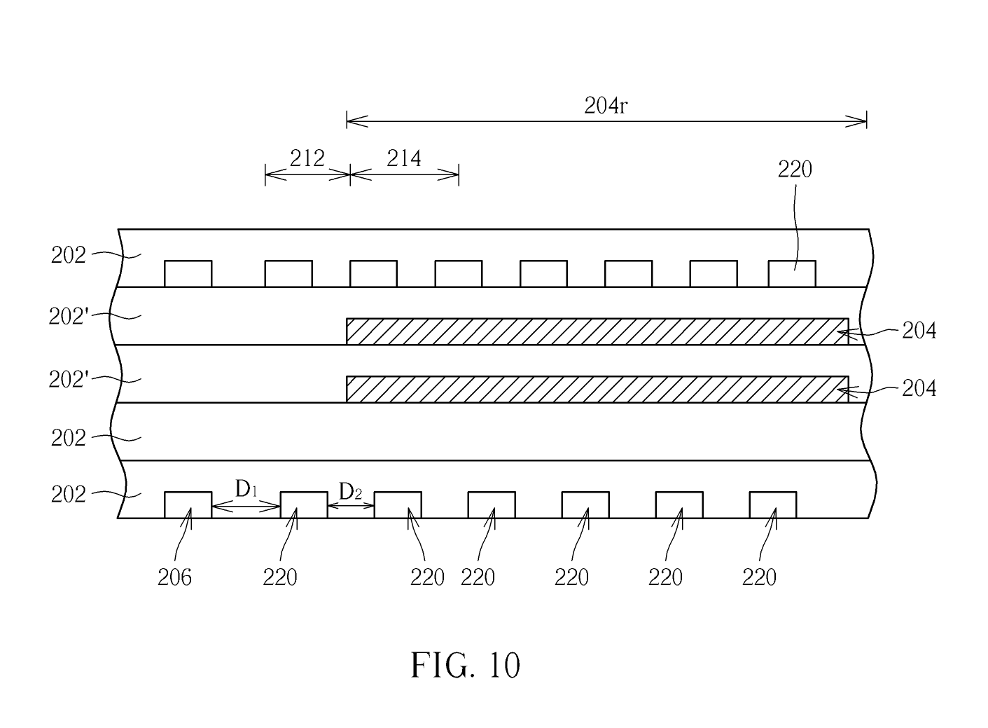

Please refer to FIGS. 2 and 5-7, wherein FIG. 5 is a flow chart of a method for manufacturing a semiconductor structure provided by a second preferred embodiment of the present invention, and FIGS. 2 and 6-7 are schematic drawings illustrating the method for manufacturing the semiconductor structure provided by the second preferred embodiment. It should be noted that elements the same in the first and second preferred embodiments are designated by the same numerals. As shown in FIG. 5, a method 300 for manufacturing a semiconductor structure is provided by the present invention, and the method 300 for manufacturing the semiconductor structure includes:

STEP 302: Providing a substrate comprising a plurality of layers

Please refer to FIG. 2 together with FIG. 5. As shown in FIG. 2, a substrate 200 including a plurality of layers 202 and 202′ (as shown in FIG. 10) formed thereon is provided. The substrate 200 can be any wafer or chip in the-state-of-art. As mentioned above, there are formed huge number of devices on the substrate 200 as a result of increased integration density. For example, devices such as at least an inductor 204, at least a MOM capacitor 206, and at least a device 208 are formed in the substrate 200 . Additionally, the device 208 is referred to any active device required in the ICs. In the preferred embodiment, the device 208 is a small device such as a MOS transistor, but not limited to this. As mentioned above, the “small device” is referred to a device having a gate layer of which a width W_{G} is smaller than 100 nm, preferably 40-70 nm. It is noteworthy that since there are plural layers 202, 202′ formed on the substrate 200, those above mentioned devices 204/206/208 can be formed on different layers, but not limited to this. Also, please note that the layers including devices formed therein are designated by 202′.

The method 300 for manufacturing the semiconductor structure provided by the preferred embodiment further includes:

STEP 304: Recognizing at least a device formed in one of the layers, the device being formed in a drawn region neighboring on a dummy-empty region

Please refer to FIG. 6 together with FIG. 5. Next, at least a device 208 formed in one of the layers is recognized. It should be noted that FIG. 6 is an enlarged view of a portion of FIG. 2. It is noteworthy that the device is always enclosed by a drawn region for marking its location and size. And the drawn region is taken as a boundary proximal to the exterior part of the device. As shown in FIG. 6, the inductor 204 is enclosed in a drawn region 204r, the capacitor 206 is enclosed in a drawn region 206r, and the small device 208 is enclosed in a drawn region 208r. More important, STEP 304 is to recognize a device formed in a drawn region neighboring on a dummy-empty region. The dummy-empty region is referred to a region that no dummy structure is formed in a 100 μm*100 μm area. For example, a device formed in a dummy block region 210 is recognized because dummy structures are avoided in the dummy block region 210. As mentioned above, areas close to the exterior part of the inductor 204 and/or the capacitor 206 are defined to the dummy block region 210, and therefore those devices will not be impacted by the dummy structures. More important, the dummy block region 210 is usually drawn to enclose not only the inductor 204 and/or the capacitor 206, but also small device 208 neighboring on the inductor 204 and/or the capacitor 206, as shown in FIG. 6. Therefore, when a small device 208 is formed in a dummy-empty region, such as the dummy block region 210, it is often recognized. As mentioned above, the dummy block region 210 is defined in not only the layer 202′ where the inductor 204 and/or the capacitor 206 are formed, but also in the layers 202 under and above the layer 202′ where the inductor 204 and/or the capacitor 206 are formed.

The method 300 for manufacturing the semiconductor structure provided by the preferred embodiment further includes:

STEP 306: Inserting a plurality of dummy structures in a first region outside of the drawing region.

Please refer to FIGS. 5 and 7 together. It is noteworthy that FIG. 7 is an enlarged view of the small device 208 and in a step subsequent to FIG. 6. After recognizing the small device 208 formed in the drawn region 208r neighboring on a dummy-empty region, a plurality of dummy structures 220 are formed in a first region 212 outside of the drawn region 208r. According to the preferred embodiment, the first region 212 includes a first width W₁, and the first width W₁ is between 5 μm and 15 μm. Therefore, the dummy structures 220 are formed in a ring shape around the drawn 208r as shown in FIG. 7.

It noteworthy that dummy structures 220 can be formed in the layer 202′ the same with the small device 208. When the dummy structures 220 and the small device 208 are formed in the same layer 202′, a distance D₁ between the dummy structures 220 and the small device 208 is larger than 0.6 μm, preferably larger than 1 μm. However, the dummy structures 220 can also be formed in the layer 202 under or above the layer 202′ where the small device 208 is formed. Furthermore, the dummy structures 220 include doped regions, polysilicon structures, or metal structures. And a distance D₂ between each dummy structure 220 is equal to or larger than 0.25 μm.

According to the method for manufacturing the semiconductor structure 300 provided by the second preferred embodiment, the small device 208 formed in a drawn region 208r neighboring on a dummy-empty region is recognized and followed by inserting/placing the dummy structures 220 in the first region 212 outside of the drawn region 208r. Accordingly, the dummy structures 220 form a dummy ring. It is noteworthy that the dummy structures 220 can be formed in the layer 202′ the same with or the layer 202 different from the layer 202′ where the small device 208 is formed. Consequently, uniformity near the small device 208, which is originally located near the dummy-empty region, is improved.

Please refer to FIGS. 2, 6 and 8-10, wherein FIG. 8 is a flow chart of a method for manufacturing a semiconductor structure provided by a third preferred embodiment of the present invention, and FIGS. 2, 6 and 9-10 are schematic drawings illustrating the method for manufacturing the semiconductor structure provided by the third preferred embodiment. It should be noted that elements the same in the first and third preferred embodiment are designated by the same numerals. As shown in FIG. 8, a method 500 for manufacturing a semiconductor structure is provided by the present invention, and the method 500 for manufacturing the semiconductor structure includes:

STEP 502: Providing a substrate comprising a plurality of layers

Please refer to FIG. 8 together with FIG. 2. As shown in FIG.

2, a substrate 200 including a plurality of layers 202 and 202′ (shown in FIG. 10) formed thereon is provided. The substrate 200 can be any wafer or chip in the-state-of-art. As mentioned above, there are formed huge number of devices on the substrate 200 as a result of increased integration density. For example, devices such as at least an inductor 204, at least a MOM capacitor 206, and at least a small device 208 are formed in the substrate 200. As mentioned above, the “small device” is referred to a device having a gate layer of which a width W_{G} is smaller than 100nm, preferably 40-70 nm. It is noteworthy that since there are plural layers 202, 202′ formed on the substrate 200, those above mentioned devices 204/206/208 can be formed on different layers, but not limited to this.

The method 500 for manufacturing the semiconductor structure provided by the preferred embodiment further includes:

STEP 504: Recognizing at least a device formed in one of the layers, the device being formed in a drawn region neighboring on a dummy-empty region

Please refer to FIG. 6 together with FIG. 8. Next, at least a device 204 formed in one of the layers is recognized. It should be noted that FIG. 6 is an enlarged view of a portion of FIG. 2. As mentioned above, each device is enclosed by a drawn region for marking its location and size. And the drawn region is taken as a boundary proximal to the exterior part of the device. As shown in FIG. 6, the inductor 204 is enclosed in a drawn region 204r, the capacitor 206 is enclosed in a drawn region 206r, and the small device 208 is enclosed in a drawn region 208r. More important, STEP 304 is performed to recognize a device formed in a drawn region neighboring on a dummy-empty region. The dummy-empty region is referred to a region that no dummy structures formed in a 100 μm*100 μm area. For example, a device formed in a dummy block region 210 is often recognized because there is no dummy structure formed nearby. In other words, the drawn regions 204r and 206r, which enclose the inductor 204 and the capacitor 206, are always neighboring on a dummy-empty region. Furthermore, it is well-known to those skilled in the art that the inductor 204 and the capacitor 206 may include a coil profile in one or more layers 202. It is noteworthy that not only no dummy structure is formed outside of the drawn regions 204r and 206r, but also no dummy structure is formed inside of the drawn regions 204r and 206r as shown in FIG. 6. Also, the dummy block region 210 defined in not only the layer 202′ where the inductor 204 and/or the capacitor 206 is formed, but also in the layers 202 under and above the layer 202′ where the inductor 204 and/or the capacitor 206 are formed. In other words, no dummy structure is formed in the layers corresponding to where the inductor 204 and/or the capacitor 206 are formed.

The method 500 for manufacturing the semiconductor structure provided by the preferred embodiment further includes:

STEP 506: Inserting a plurality of dummy structures in a first region outside of the drawing region.

STEP 508: Inserting a plurality of dummy structures in a second region inside of the drawing region.

Please refer to FIGS. 8-10 together, FIG. 9 is an enlarged view of the inductor 204, and FIG. 10 is a cross-sectional view taken along a Line B-B′ of FIG. 9. It is noteworthy that STEP 506 and STEP 508 are performed simultaneously in the preferred embodiment, but not limited to this. After recognizing the inductor 204 formed in the drawn region 204r neighboring on a dummy-empty region, a plurality of dummy structures 220 are inserted and formed in a first region 212 outside of the drawn region 204r and in a second region 214 inside of the drawn region 210. According to the preferred embodiment, the first region 212 includes a first width W₁, and the first width W₁ is between 15 μm and 30 μm. And the second region 214 comprises a second width W₂, and the second width W₂ is between 5 μm and 15 μm. Therefore, the dummy structures 220 (formed in the first region 212 and the second region 214) are formed in a ring shape around the drawn region 204r as shown in FIG. 9. More important, the dummy structures 220 are formed in the layer 202 different from the layer 202 where the inductor 204 is formed, and therefore the dummy structures 220 are depicted by the dotted lines in FIG. 9.

Furthermore, it should be noted that though that dummy structures 220 and the inductor 204 are formed in different layers 202, 202, the dummy structures 220 can be formed in the layer where other device or interconnections formed in. For example but not limited to, in the preferred embodiment, the dummy structures 220 and the small device 208 are formed in the same layer 202. It should be noted that a smallest distance D₁ between the small device 208 and the dummy structure proximal to the small device 208 is larger than 0.6 μm, preferably larger than 111m as shown in FIG. 9. Furthermore, the dummy structures 220 include doped regions, polysilicon structures, or metal structures. And a distance D₂ between each dummy structure 220 is equal to or larger than 0.25 μm. It should be easily realized by those skilled in the art that though the size and density of the dummy structures 220 in the first region 212 and the second region 214 are the same, the size and the density of the dummy structures 220 in the first region 212 can be different from that of the dummy structures 220 in the second region 214 if required.

According to the method for manufacturing the semiconductor structure 500 provided by the third preferred embodiment, the inductor 204 formed in a drawn region 204r neighboring on a dummy empty region is recognized and followed by inserting/placing the dummy structures 220 in the first region 212 and the second region 214 to form a dummy ring. It is noteworthy that the dummy structures 220 and the inductor 204 are formed in different layers 202, 202′, therefore the dummy structures 220 are formed in the first region 212 correspondingly outside of the drawing region 204r and in a second region 214 correspondingly inside of the drawing region 204r. Consequently, uniformity in the layers 202 above and under the inductor 204 is improved. Additionally, though the preferred embodiment uses the inductor 204 as the example, those skilled in the art should easily realize that the dummy structure 220 can be formed in a first region outside of the drawn region 206r, in which the capacitor 206 is formed, and the a second region inside of the draw region 206r according to the abovementioned steps.

According to the semiconductor device and manufacturing method thereof, a dummy block region or a device neighboring on a dummy-empty region is recognized and thus the dummy structures are inserted into the dummy block region or the dummy-empty region. The inserted dummy structures are able to maintain uniform pattern density, and therefore those devices in the dummy block region or neighboring on the dummy-empty region are protected.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure comprising:
a substrate comprising a plurality of layers formed thereon;
at least a first device formed in one of the layers formed thereon;
a drawn region enclosing the first device; and
a plurality of dummy structures formed in another layer, the dummy structures being formed in a first region correspondingly outside of the drawing region and in a second region correspondingly inside of the drawing region.

2. The semiconductor structure according to claim 1, wherein the first region comprises a first width, and the first width is between 15 μm and 30 μm.

3. The semiconductor structure according to claim 1, wherein the second region comprises a second width, and the second width is between 5 μm and 15 μm.

4. The semiconductor structure according to claim 1, wherein the first device comprises an inductor or a metal-oxide-metal (MOM) capacitor.

5. The semiconductor structure according to claim 1, further comprising at least a second device formed on the substrate.

6. The semiconductor structure according to claim 5, wherein the second device comprises at least a gate layer, and a width of the gate layer is smaller than 100nm.

7. The semiconductor structure according to claim 5, wherein the second device and the dummy structures are formed in a same layer, and a smallest distance between the second device and the dummy structures is larger than 0.6 μm.

8. The semiconductor structure according to claim 1, wherein the first device is formed neighboring on a dummy empty region.

9. A method for manufacturing a semiconductor structure, comprising:
providing a substrate comprising a plurality of layers formed thereon;
recognizing at least a dummy block region in one of the layers, the dummy block region comprising at least a device formed therein; and
inserting a plurality of dummy structures in a first region outside of the dummy block region and in a second region inside of the dummy block region in the layer.

10. The method for manufacturing the semiconductor structure according to claim 9, wherein the first region comprises a first width, and the first width is between 15 μm and 30 μm.

11. The method for manufacturing the semiconductor structure according to claim 9, wherein the second region comprises a second width, and the second width is between 5 μm and 15 μm.

12. The method for manufacturing the semiconductor structure according to claim 9, wherein a smallest distance between the dummy structures and the device is larger than 0.6 μm.

13. The method for manufacturing the semiconductor structure according to claim 9, wherein the dummy structures comprise diffusion regions, polysilicon regions, or metal structures.

14. A method for manufacturing a semiconductor structure, comprising:
providing a substrate comprising a plurality of layers formed thereon;
recognizing at least a device formed in one of the layers, the device being formed in a drawn region neighboring on a dummy-empty region; and
inserting a plurality of dummy structures in a first region outside of the drawing region.

15. The method for manufacturing the semiconductor structure according to claim 14, wherein the first region comprises a first width, and the first width is between 5 μm and 15 μm.

16. The method for manufacturing the semiconductor structure according to claim 15, wherein the device comprises a gate layer, and a width of the gate layer is smaller than 100 nm.

17. The method for manufacturing the semiconductor structure according to claim 15, wherein the dummy structures and the device are formed in the same layer.

18. The method for manufacturing the semiconductor structure according to claim 14, wherein the first region comprises a first width, and the first width is between 15 μm and 30 μm.

19. The method for manufacturing the semiconductor structure according to claim 18, further comprising simultaneously inserting the dummy structures in a second region correspondingly inside of the drawn region, the second region comprises a second width, and the second width is between 5 μm and 15 μm.

20. The method for manufacturing the semiconductor structure according to claim 19, wherein the dummy structures and the device are formed in different layers.
